(19) United States
(12) Patent Application Publication
(10) Pub. No.: US 2025/0203818 A1
(43) Pub. Date: Jun. 19, 2025

(54) SPEAKER BOX

(71) Applicants: AAC ACOUSTIC TECHNOLOGIES (SHENZHEN) CO., LTD., Shenzhen (CN); AAC MICROTECH (CHANGZHOU) CO., LTD., Changzhou City, Jiangsu Province (CN)

(72) Inventors: Shuwen Wu, Shenzhen (CN); Zhenfan Ge, Shenzhen (CN)

(21) Appl. No.: 17/921,977

(22) PCT Filed: Apr. 20, 2022
(86) PCT No.: PCT/CN2022/087900

§ 371 Date: Mar. 12, 2025

(30) Foreign Application Priority Data
Apr. 7, 2022 (CN) 202210361090.1

(51) Int. Cl. H05K 7/20; H04R 1/02

(52) U.S. Cl. CPC H05K 7/2039; H04R 1/025; H05K 7/20218

(57) ABSTRACT

The present application discloses a speaker box, including a casing with an accommodating cavity, and a sounding unit fixed in the accommodating cavity and dividing the accommodating cavity into a closed rear acoustic cavity and a front acoustic cavity communicated with an outside of the casing. A heat exchange cavity is arranged within a wall of the accommodating cavity, and the heat exchange cavity is filled with a heat exchange medium. Compared with the prior art, in the present application, the heat exchange cavity filled with the heat exchange medium is arranged in the casing. When the speaker box is in the working state, the sounding unit vibrates and generates heat, and the heat is conducted to the heat exchange medium through a wall of the accommodating cavity. The heat exchange medium is in contact with the outside air for heat exchange to release heat, thereby improving the heat dissipation efficiency of the speaker box.

### TECHNICAL FIELD

The present application relates to the technical field of electro-acoustic conversion, in particular to a speaker box.

### BACKGROUND

Speaker boxes are widely adopted in portable mobile electronic products, such as mobile phones, to convert audio signals into sound for playback. The speaker box has high loudness and good low-frequency sound effects.

A speaker box in the prior art includes a front cover, a rear cover covered on the front cover and enclosing an accommodating space with the front cover, and a sounding body accommodated in the accommodating space, and the sounding body divides the accommodating space into a front cavity and a rear cavity. However, the speaker box with poor heat dissipation in the related art limits acoustic performance.

### SUMMARY OF THE INVENTION

### Technical Problem

In view of the above-mentioned problem, the present application provides a speaker box, so as to solve the technical problem in the related art, making the speaker box have good heat dissipation.

### Solution to the Problem

### Technical Solution

In a first aspect, the present application provides a speaker box, comprising:
a casing with an accommodating cavity;
a sounding unit, fixed in the accommodating cavity and dividing the accommodating cavity into a closed rear acoustic cavity and a front acoustic cavity communicated with an outside of the casing;
wherein a heat exchange cavity is arranged within a wall of the accommodating cavity, and the heat exchange cavity is filled with a heat exchange medium.

The speaker box as above, wherein, preferably, the sounding unit comprises a supporting body and a sounding body, wherein:
a first end of the supporting body is accommodated in the accommodating cavity;
and the casing is provided with a first groove communicated with the accommodating cavity; a second end of the supporting body is extended outside the casing through the first groove, the supporting body is provided with a second groove and a third groove; the second groove is arranged through the first end of the supporting body; one end of the third groove is arranged at the second end of the supporting body to form an opening, and the other end of the third groove is extended to communicate with the second groove;
the sounding body is supported on the second groove; the sounding body, the accommodating cavity, the second groove and the third groove together form the front acoustic cavity, and the sounding body, the supporting body and the accommodating cavity together form the closed rear acoustic cavity.

The speaker box as above, wherein, preferably, the casing comprises a top wall, a bottom wall and a peripheral wall, the top wall and the bottom wall, wherein the top wall and the bottom wall are arranged at intervals, and the peripheral wall is connected to the top wall and the bottom wall; the accommodating cavity is enclosed by the top wall, the bottom wall and the peripheral wall; the first groove is opened on the peripheral wall, and the supporting body and the heat exchange cavity are both arranged on the bottom wall.

The speaker box as above, wherein, preferably, the casing comprises a front cover and a rear cover which are respectively covered on opposite sides of the sounding body along a vibration direction of the sounding body; the rear cover comprises a main plate arranged opposite to the front cover and a side plate bent and extended in a direction of the front cover from an outer peripheral edge of the main plate and fixedly connected to the front cover; the side plate is abutted against the front cover for sealing and fixing; a wall of the main plate forms the top wall; a wall of the side plate forms the peripheral wall, and a wall of the front cover forms the bottom wall.

The speaker box as above, wherein, preferably, the heat exchange cavity is arranged on an edge of the bottom wall.

The speaker box as above, wherein, preferably, the edge of the bottom wall is recessed to form a fourth groove, and the bottom wall is further provided with a cover plate for closing the fourth groove; the heat exchange cavity is enclosed by an inner wall of the cover plate and a groove wall of the fourth groove.

The speaker box as above, wherein, preferably, the casing and the cover plate are made of metal.

The speaker box as above, wherein, preferably, the cover plate and the bottom wall are bonded and sealed by welding.

The speaker box as above, wherein, preferably, the second groove is a stepped groove.

The speaker box as above, wherein, preferably, the peripheral wall is provided with a fifth groove connected to the rear acoustic cavity; the casing is provided with a sealing cover attached to the casing, and the sealing cover is completely covered the fifth groove.

### Beneficial Effect of the Invention

### Beneficial Effect

Compared with the related art, in the present application, a heat exchange cavity filled with a heat exchange medium is arranged in the casing. When the speaker box is in a working state, the sounding unit vibrates and generates heat, and the heat is conducted to the heat exchange medium through a wall of the accommodating cavity, and then the heat exchange medium is in contact with the external air for heat exchange to release the heat, thereby improving the heat dissipation efficiency of the speaker box.

Described above is only an overview of the technical solutions of the present application, in order to understand the technical means of the present application more clearly, it may be implemented according to the content of the description. Besides, in order to make the above and other objects, features and advantages of the present application are more obvious and are easy to understand, the following specific embodiments of the present application are provided.

### BRIEF DESCRIPTION OF THE DRAWINGS

### Description of the Drawings

Various other advantages and benefits will become apparent to those of ordinary skill in the art upon reading the following detailed description of the preferred embodiments. The drawings are used for the purpose of illustrating preferred embodiments only and are not to limit the present application. Besides, the same components are denoted by the same reference numbers throughout the accompanying drawings. In the accompanying drawings:

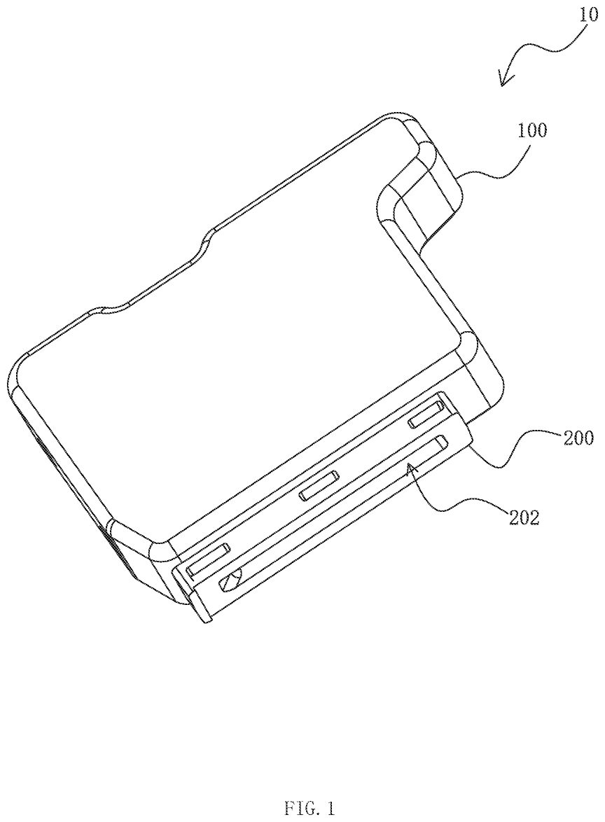

FIG. 1 is a perspective view of an overall structure according to an embodiment of the present application.

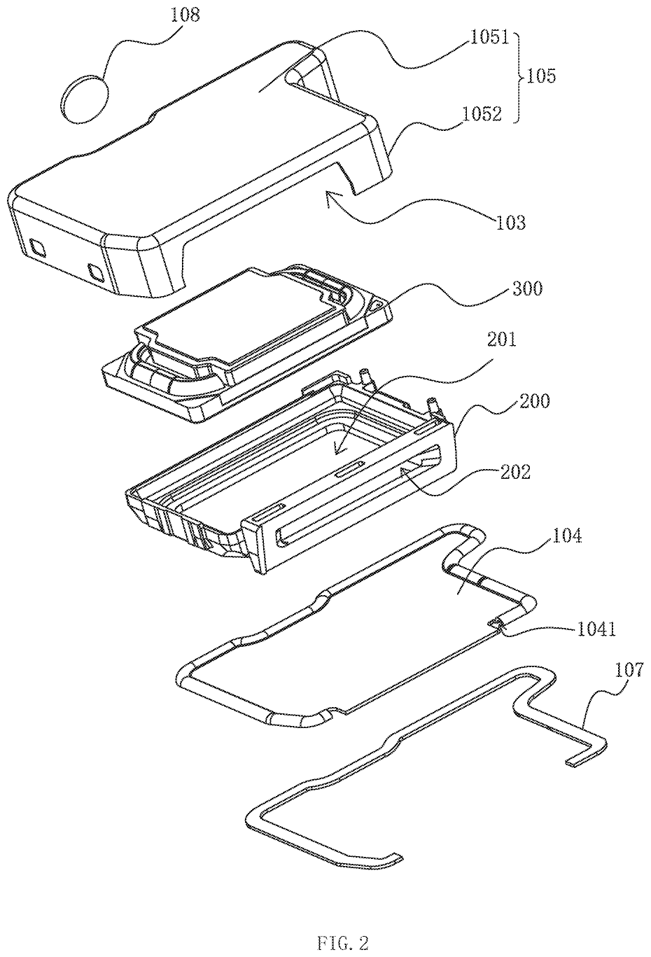

FIG. 2 is an exploded view of the overall structure according to an embodiment of the present application.

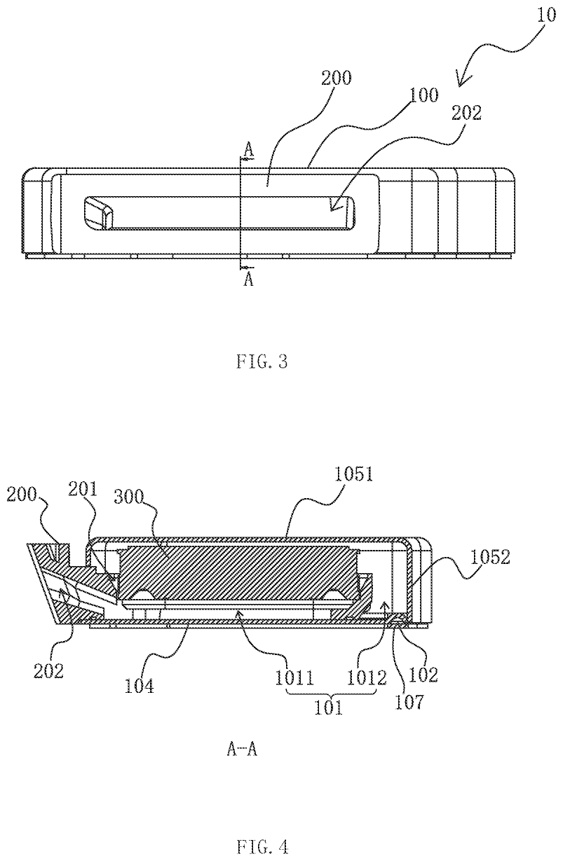

FIG. 3 is a front view of the overall structure according to an embodiment of the present application.

FIG. 4 is a sectional view of the overall structure in FIG. 3 along a direction of A-A.

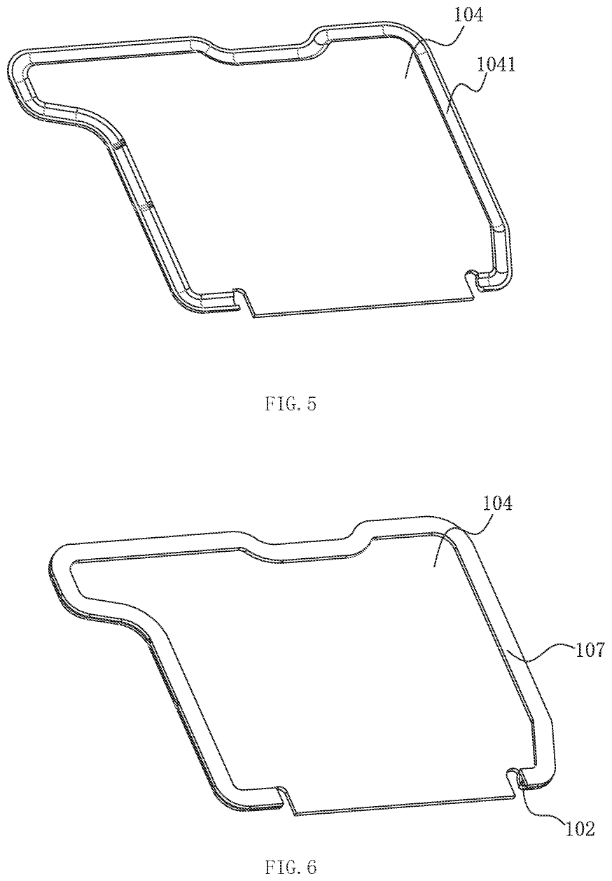

FIG. 5 is a perspective view of a front cover according to an embodiment of the present application.

FIG. 6 is a perspective view illustrating a state in which the front cover and the cover plate are combined according to an embodiment of the present application.

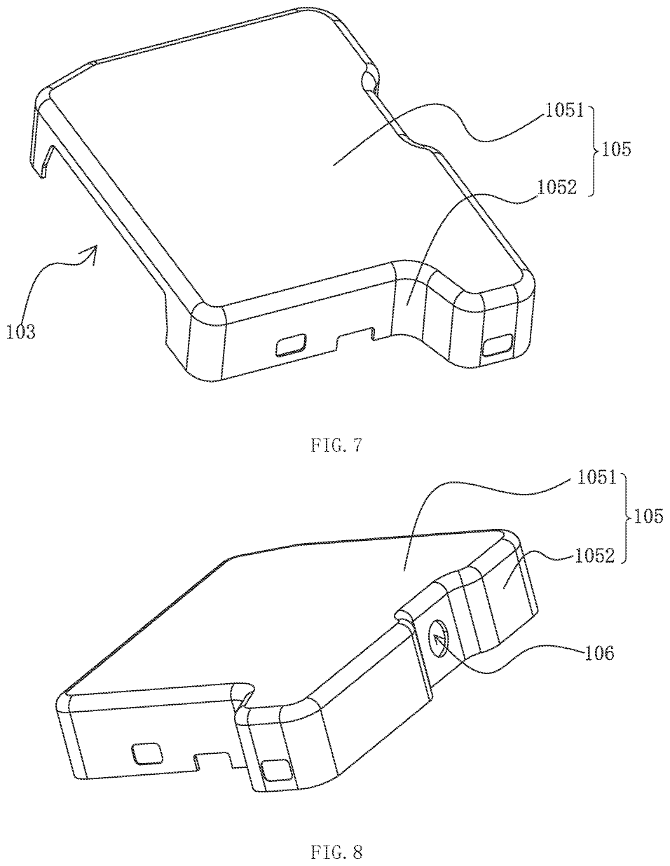

FIG. 7 is a perspective view of a rear cover from one angle according to an embodiment of the present application.

FIG. 8 is a perspective view of the rear cover from another angle according to an embodiment of the present application.

In the accompanying drawings, the structures are not necessarily drawn to practical scale.

The reference numbers in the specific embodiments are as follows:
10—speaker box;
100—casing, 101—accommodating cavity, 1011—front acoustic cavity, 1012—rear acoustic cavity, 102—heat exchange cavity, 103—first groove, 104—front cover, 1041—fourth groove, 105—rear cover, 1051—main plate, 1052—side plate, 106—fifth groove, 107—cover plate, 108—sealing cover;
200—supporting body, 201—second groove, 202—third groove;
300—sounding body.

### Best Embodiments for Practicing the Invention

### Best Embodiments for the Invention

The embodiments described below with reference to the accompanying drawings are exemplary and are only used to explain the present application, but not to be construed as a limitation of the present application.

The speaker box in the related art has the technical defect of poor heat dissipation. it is found from researches that when the sounding unit in the speaker box is in a working state, the generated heat is transmitted to the rear acoustic cavity and the front acoustic cavity through the air for heat dissipation. On the one hand, a bracket for supporting the sounding body is a plastic structure, which has poor thermal conductivity and low heat dissipation efficiency. On the other hand, the hot air in the rear acoustic cavity is trapped in the rear acoustic cavity, and can only contact the outside air through a leak hole, resulting in poor heat dissipation and limited acoustic performance.

In order to improve the heat dissipation performance of the speaker box 10, as shown in FIGS. 1-8, the present application provides a speaker box 10, including a casing 100 and a sounding unit.

The interior of the casing 100 has an accommodating cavity 101, and the sounding unit is fixed in the accommodating cavity 101. The sounding unit has a diaphragm for vibrating and sounding. The sounding unit divides the accommodating cavity 101 into a closed rear acoustic cavity 1012 and a front acoustic cavity 1011 communicated with an outside of the casing 100, and the diaphragm is accommodated in the front acoustic cavity 1011.

A heat exchange cavity 102 is provided within a wall of the accommodating cavity 101, and the heat exchange cavity 102 is located in the front acoustic cavity 1011 and/or the rear acoustic cavity 1012. Preferably, the heat exchange cavity 102 is located in a wall where the rear acoustic cavity 1012 is located. The heat exchange cavity 102 is filled with a heat exchange medium. In an embodiment, the heat exchange medium is cooling liquid. When the speaker box 10 is in a working state, the sounding body vibrates and generates heat, and the heat is conducted to the heat exchange medium through the wall of the heat exchange cavity 102, and then the heat exchange medium is in contact with the external air to conduct heat exchange and release heat, thereby improving the heat dissipation efficiency of the speaker box 10.

Further, as shown in FIG. 2, FIG. 4 and FIG. 7, the sounding unit includes a supporting body 200 and a sounding body 300.

A first end of the supporting body 200 is fixedly accommodated in the accommodating cavity 101. The casing 100 is provided with a first groove 103 communicated with the accommodating cavity 101. A second end of the supporting body 200 is extended outside the casing 100 through the first groove 103. In an embodiment, the supporting body 200 is made of plastic material and has an annular structure. The supporting body 200 is provided with a second groove 201 and a third groove 202. The second groove 201 is arranged through the first end of the supporting body 200. One end of the third groove 202 is arranged on the second end of the supporting body 200 to form an opening. The opening is located outside the casing 100. The other end of the third groove 202 is extended to communicate with the second groove 201. The above structure forms a side sounding structure of the speaker box 10, making a shape of the speaker box 10 match a shape of the whole machine, which is beneficial to a flexible assembly of the speaker box 10 in the whole machine.

The sounding body 300 is supported on the second groove 201. A side of the sounding body 300 with the diaphragm is arranged toward the second groove 201, and is spaced from an inner wall of the accommodating cavity 101. A groove wall of the second groove 201 surrounds a peripheral side of the sounding body 300. The sounding body 300 and the second groove 201 are sealed and fixed. The sounding body 300, the accommodating cavity 101, the second groove 201 and the third groove 202 together form the front acoustic cavity 1011. The sounding body 300, the supporting body 200 and the accommodating cavity 101 together form the closed rear acoustic cavity 1012.

Further, the casing 100 includes a top wall, a bottom wall and a peripheral wall. The top wall and the bottom wall are arranged at intervals. The peripheral wall is connected to the top wall and the bottom wall. The accommodating cavity 101 is enclosed by the top wall, the bottom wall and the peripheral wall. The first groove 103 is opened on the peripheral wall. The supporting body 200 and the heat exchange cavity 102 are both arranged on the bottom wall. The sounding body 300 is supported on the supporting body 200, so as to vibrate and sound on the bottom wall. The heat is concentrated on the bottom wall, and the heat exchange cavity 102 is also arranged on the bottom wall. The heat exchange cavity 102 has a better heat conduction effect, thereby improving the heat dissipation effect.

In some embodiments, the casing 100 is in a split structure, so as to facilitate molding, processing and assembly. Specifically, the casing 100 includes a front cover 104 and a rear cover 105 that are respectively covered on opposite sides of the sounding body 300 along a vibration direction of the diaphragm of the sounding body 300. The front cover 104 is a plate structure. The rear cover 105 includes a main plate 1051 opposite to the front cover 104 and a side plate 1052 bent and extended toward the front cover 104 from a periphery of the main plate 1051 and fixedly connected to the front cover 104. The side plate 1052 is abutted against the front cover 104 for sealing and fixing. A wall of the main plate 1051 forms the top wall. A wall of the side plate 1052 forms the peripheral wall. A wall of the front cover 104 forms the bottom wall, and the supporting body 200 is fixed to the front cover 104.

Further, the heat exchange cavity 102 is arranged on an edge of the front cover 104, and the heat exchange cavity 102 is arranged around the sounding body 300 and is close to a connecting portion between the front cover 104 and the rear cover 105, so that the heat exchange cavity 102 can have both the heat dissipation function of the front cover 104 and the rear cover 105. The heat generated by the vibration of the sounding body 300 is transferred to the heat exchange cavity 102 through the front cover 104, and then cooled by the heat exchange between the cooling liquid and the air in the heat exchange cavity 102. An extension direction of the heat exchange cavity 102 matches a shape of an edge of the front cover 104, making the speaker box easier to form, has better thermal conductivity, and has more advantages in heat dissipation.

Further, as shown in FIGS. 5-6, the edge of the front cover 104 is recessed from the outside of the casing 100 toward the inside of the accommodating cavity 101 to form a fourth groove 1021. An extending direction of the fourth groove 1021 is the matched with a shape of the edge of the front cover 104. The front cover 104 is further provided with a cover plate 1041 for closing the fourth groove 1021. The cover plate 1041 is attached to a surface of the front cover 104 on both sides of the fourth groove 1021 to completely seal the fourth groove 1021. An inner wall of the cover plate 1041 and a groove wall of the fourth groove 1021 encloses the heat exchange cavity 102.

In some embodiments, a preparation process of the heat exchange cavity 102 is as follows.

Step 1: the cover plate 1041 is punched and shaped using a steel sheet.

Step 2: the front cover 104 is formed by punching and bending the steel sheet.

Step 3: the cover plate 1041 and the front cover 104 are welded and sealed to form the heat exchange cavity 102, and both ends of the heat exchange cavity 102 are opened to form injection ports.

Step 4: the cooling liquid is injected into the heat exchange chamber 102 through the injection ports, and the injection ports are sealed with glue or welding after injection.

Further, the casing 100 and the cover plate 1041 are both made of metal. On the premise of ensuring a structural strength of the casing 100, the casing 100 made of metal may be designed to be thinner than the all-plastic casing 100. Moreover, since the front cover 104 and the rear cover 105 made of metal materials can be fixed by metal welding, there is no need to reserve more space for ultrasonic welding. While assembling the sounding body 300 effectively, the metal casing greatly increases the volume of the cavity of the casing 100, and effectively increases a volume of the rear acoustic cavity 1012 enclosed by the sounding body 300 and the casing 100, thereby improving the acoustic performance of the speaker box 10, especially the low-frequency acoustic performance. Besides, the metal casing 100 and the cover plate 1041 has good thermal conductivity. When the diaphragm in the sounding body 300 is in a working state, the heat generated by the vibration is conducted more quickly and efficiently on the casing 100 and the cover plate 1041, thereby improving the overall heat dissipation performance of the speaker box 10.

Further, as shown in FIG. 4, the second groove 201 is a stepped groove with a groove portion that is gradually bent and contracted. The sounding body 300 is fixed in the stepped groove, and the sounding body 300 and the supporting body 200 can be overlapped in a thickness direction of the supporting body 200, thereby reducing a space occupied by the sounding body 300, which is beneficial to the miniaturization of the speaker box 10.

Further, as shown in FIG. 2 and FIG. 8, the side plate 1052 is provided with a fifth groove 106 communicated with the rear acoustic cavity 1012. The casing 100 is provided with a sealing cover 108 attached to the casing 100. The sealing cover 108 is completely covered on the fifth groove 106. The fifth groove 106 is configured to improve the air pressure balance between the rear acoustic cavity 1012 and the outside world. The sealing cover 108 can seal the fifth groove 106 after the sound-absorbing material is filled into the rear acoustic cavity 1012 through the fifth groove 106, so that the assembly of the speaker box 10 is simpler and more reliable.

The structure, features and effects of the present application have been described in detail above according to the embodiments shown in the drawings. Described above are only preferred embodiments of the present application, but the scope of implementation of the present application is not limited by the drawings. Any changes made in accordance with the concept of the present application, or modifications to equivalent embodiments with equivalent changes without exceeding the spirit covered by the description and drawings shall fall within the protection scope of the present application.

What is claimed is:

1. A speaker box, comprising:
a casing with an accommodating cavity;
a sounding unit, fixed in the accommodating cavity and dividing the accommodating cavity into a closed rear acoustic cavity and a front acoustic cavity communicated with an outside of the casing;
wherein a heat exchange cavity is arranged within a wall of the accommodating cavity, and the heat exchange cavity is filled with a heat exchange medium.

2. The speaker box of claim 1, wherein the sounding unit comprises a supporting body and a sounding body, wherein:
a first end of the supporting body is accommodated in the accommodating cavity; the casing is provided with a first groove communicated with the accommodating cavity, and a second end of the supporting body is extended outside the casing through the first groove; the supporting body is provided with a second groove and a third groove; the second groove is arranged through the first end of the supporting body; one end of the third groove is arranged at the second end of the supporting body to form an opening, and the other end of the third groove is extended to communicate with the second groove;
the sounding body is supported on the second groove; the sounding body, the accommodating cavity, the second groove and the third groove together form the front acoustic cavity, and the sounding body, the supporting body and the accommodating cavity together form the closed rear acoustic cavity.

3. The speaker box of claim 2, wherein the casing comprises a top wall, a bottom wall and a peripheral wall, the top wall and the bottom wall, wherein the top wall and the bottom wall are arranged at intervals, and the peripheral wall is connected to the top wall and the bottom wall; the accommodating cavity is enclosed by the top wall, the bottom wall and the peripheral wall; the first groove is opened on the peripheral wall, and the supporting body and the heat exchange cavity are both arranged on the bottom wall.

4. The speaker box of claim 3, wherein the casing comprises a front cover and a rear cover which are respectively covered on opposite sides of the sounding body along a vibration direction of the sounding body; the rear cover comprises a main plate arranged opposite to the front cover and a side plate bent and extended in a direction of the front cover from an outer peripheral edge of the main plate and fixedly connected to the front cover; the side plate is abutted against the front cover for sealing and fixing; a wall of the main plate forms the top wall; a wall of the side plate forms the peripheral wall, and a wall of the front cover forms the bottom wall.

5. The speaker box of claim 3, wherein the heat exchange cavity is arranged on an edge of the bottom wall.

6. The speaker box of claim 5, wherein the edge of the bottom wall is recessed to form a fourth groove, and the bottom wall is further provided with a cover plate for closing the fourth groove; the heat exchange cavity is enclosed by an inner wall of the cover plate and a groove wall of the fourth groove.

7. The speaker box of claim 6, wherein the casing and the cover plate are made of metal.

8. The speaker box of claim 7, wherein the cover plate and the bottom wall are bonded and sealed by welding.

9. The speaker box of claim 2, wherein the second groove is a stepped groove.

10. The speaker box of claim 3, wherein the peripheral wall is provided with a fifth groove connected to the rear acoustic cavity; the casing is provided with a sealing cover attached to the casing, and the sealing cover is completely covered the fifth groove.
